(19) United States
(12) Patent Application Publication
(10) Pub. No.: US 2016/0006275 A1
(43) Pub. Date: Jan. 7, 2016

(54) SYSTEM AND METHOD FOR BATTERY OPEN CIRCUIT VOLTAGE ESTIMATION

(71) Applicant: FORD GLOBAL TECHNOLOGIES, LLC, Dearborn, MI (US)

(72) Inventors: Tae-Kyung LEE, Ann Arbor, MI (US); Dawn BERNARDI, Sterling Heights, MI (US)

(21) Appl. No.: 14/321,284

(22) Filed: Jul. 1, 2014

(51) Int. Cl. H02J 7/00; G01R 31/36; G01R 31/00; B60L 11/18

(52) U.S. Cl. CPC H02J 7/0013; B60L 11/1861; G01R 31/3648; G01R 31/005; G01R 31/3606; H02J 7/007

(57) ABSTRACT

A vehicle includes a battery pack and at least one controller. The at least one controller outputs open circuit voltage data for a given state of charge of the battery pack based on model parameters of battery pack positive and negative electrodes represented by normalized Li-ion concentrations at zero and one hundred percent states of charge, and model parameters of at least two open circuit voltages each associated with a different state of charge.

### TECHNICAL FIELD

The present disclosure relates to battery management techniques capable of estimating parameters of elements forming a battery model for providing control of an associated battery.

### BACKGROUND

Hybrid electric vehicles (HEV) utilize a combination of an internal combustion engine with an electric motor to provide motive power. This arrangement provides improved fuel economy over a vehicle that has only an internal combustion engine. One method of improving the fuel economy in an HEV is to shutdown the engine during times that the engine operates inefficiently, and is not otherwise needed to propel the vehicle. In these situations, the electric motor is used to provide all of the power needed to propel the vehicle. When the driver power demand increases such that the electric motor can no longer provide enough power to meet the demand, or in other cases such as when the battery state of charge (SOC) drops below a certain level, the engine should start quickly and smoothly in a manner that is nearly transparent to the driver.

The HEV includes a battery management system that estimates values descriptive of the battery pack and/or battery cell present operating conditions. The battery pack and/or cell operating conditions include battery SOC, power fade, capacity fade, and instantaneous available power. The battery management system should be capable of estimating values during changing cell characteristics as cells age over the lifetime of the pack.

### SUMMARY

A battery management system includes a battery pack and at least one controller. The at least one controller inputs current to the battery pack at each of at least two different states of charge. The at least one controller also outputs open circuit voltage data for a state of charge other than the at least two different states of charge based on model parameters of positive and negative electrodes derived from open circuit voltage measurements corresponding to the input.

### BRIEF DESCRIPTION OF THE DRAWINGS

FIG. 1 is a schematic diagram of a hybrid-electric vehicle illustrating typical drivetrain and energy storage components;

FIG. 2 is a schematic diagram of a battery model having current inputs and voltage outputs;

FIG. 3 is a graph of identified open circuit voltage profiles from the interpolation of a number of open circuit voltage measurements;

FIG. 4 is a graph illustrating the open circuit voltage calculation of a battery cell from open circuit voltage curves of a positive electrode and a negative electrode at a given state of charge;

FIG. 5 is a flow chart of an algorithm for identifying open circuit voltage curves in a battery management system;

FIGS. 6A and 6B are graphs of identified open circuit voltage curves and identified lithiation limits of each electrode with a different number of open circuit potential measurement points;

FIG. 7 are graphs of an identified open circuit voltage curve and identified lithiation limits of each electrode of a battery cell as the cell ages over the lifetime of the battery pack;

FIG. 8A is a graph illustrating an identified open circuit voltage curve by a number of open circuit voltage measurements, and

FIG. 8B is a graph illustrating an identified open circuit voltage curve using two or more electrodes at a given Li-ion concentration.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

The embodiments of the present disclosure generally provide for a plurality of circuits or other electrical devices. All references to the circuits and other electrical devices and the functionality provided by each are not intended to be limited to encompassing only what is illustrated and described herein. While particular labels may be assigned to the various circuits or other electrical devices disclosed, such labels are not intended to limit the scope of operation for the circuits and the other electrical devices. Such circuits and other electrical devices may be combined with each other and/or separated in any manner based on the particular type of electrical implementation that is desired. It is recognized that any circuit or other electrical device disclosed herein may include any number of microprocessors, integrated circuits, memory devices (e.g., FLASH, random access memory (RAM), read only memory (ROM), electrically programmable read only memory (EPROM), electrically erasable programmable read only memory (EEPROM), or other suitable variants thereof) and software which co-act with one another to perform operation(s) disclosed herein. In addition, any one or more of the electric devices may be configured to execute a computer-program that is embodied in a non-transitory computer readable medium that is programmed to perform any number of the functions as disclosed.

An HEV battery system may implement a battery management strategy that estimates values descriptive of the present operating condition of the battery and/or one or more battery cells. The battery pack and/or one or more cells operating conditions include battery state of charge, power fade, capacity fade, and instantaneous available power. The battery management strategy may be capable of estimating values as cells age over the lifetime of the pack. The precise estimation of some parameters may improve performance and robustness, and may ultimately lengthen the useful lifetime of the battery pack. For the battery system described herein, estimation of some battery pack and/or cell parameters can be realized as discussed below.

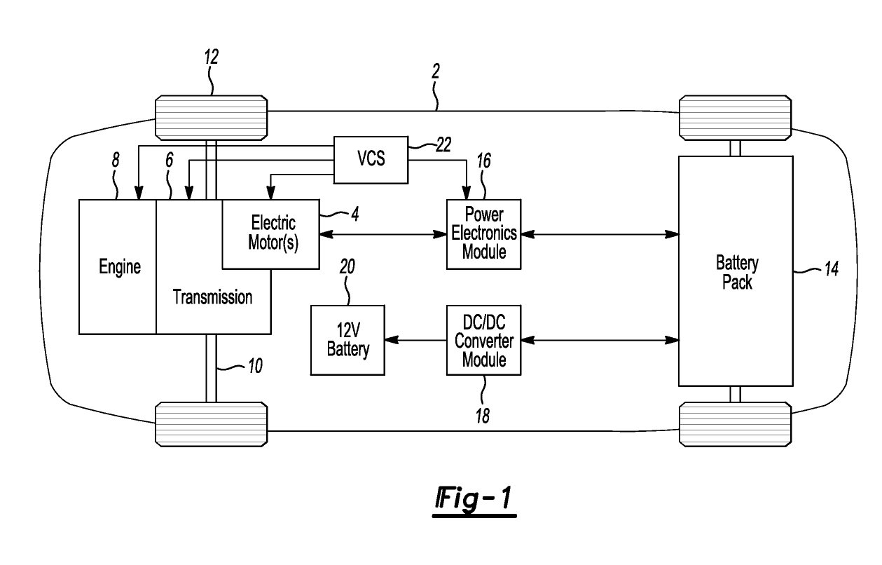

FIG. 1 depicts a typical hybrid-electric vehicle. A typical hybrid-electric vehicle 2 may comprise one or more electric motors 4 mechanically connected to a hybrid transmission 6. In addition, the hybrid transmission 6 is mechanically connected to an engine 8. The hybrid transmission 6 is also mechanically connected to a drive shaft 10 that is mechanically connected to the wheels 12. In another embodiment not depicted in the illustration, the hybrid transmission may be a non-selectable gear transmission that may include at least one electric machine. The electric motors 4 can provide propulsion and deceleration capability when the engine 8 is turned on or off. The electric motors 4 also act as generators and can provide fuel economy benefits by recovering energy that would normally be lost as heat in the friction braking system. The electric motors 4 may also provide reduced pollutant emissions since the hybrid electric vehicle 2 may be operated in electric mode under certain conditions.

A battery pack 14 may include a traction battery having one or more battery cells that store energy which can be used by the electric motors 4. The vehicle battery pack 14 typically provides a high voltage DC output and is electrically connected to a power electronics module 16. The power electronics module 16 may communicate with one or more control modules that make up a vehicle computing system 22. The vehicle computing system 22 may control several vehicle features, systems, and/or subsystems. The one or more modules may include, but are not limited to, a battery management system. The power electronics module 16 is also electrically connected to the electric motors 4 and provides the ability to bi-directionally transfer energy between the battery pack 14 and the electric motors 4. For example, a typical battery pack 14 may provide a DC voltage while the electric motors 4 may require three-phase AC current to function. The power electronics module 16 may convert the DC voltage to a three-phase AC current as required by the electric motors 4. In a regenerative mode, the power electronics module 16 will convert the three-phase AC current from the electric motors 4 acting as generators to the DC voltage required by the battery pack 14.

In addition to providing energy for propulsion, the battery pack 14 may provide energy for other vehicle electrical systems. A typical system may include a DC/DC converter module 18 that converts the high voltage DC output of the battery pack 14 to a low voltage DC supply that is compatible with other vehicle loads. Other high voltage loads may be connected directly without the use of a DC/DC converter module 18. In a typical vehicle, the low voltage systems are electrically connected to a 12V battery 20.

The battery pack 14 may be controlled by the power electronics module 16 which may receive commands from a vehicle computing system 22 having one or more control modules. The one or more control modules may include a battery control module. The one or more control modules may be calibrated to control the battery pack 14 using a battery model parameter estimation method which estimates an average sense of effective battery internal resistance during operation to determine battery power capability. The power capability prediction enables the battery pack 14 to prevent over-charging and over-discharging.

The battery parameter prediction method and/or strategy may assist in determining battery current limits and power capability in real-time (i.e., during operation). Many battery parameter estimation processes are affected by the fidelity of battery models and unpredicted environmental conditions or unexpected noises during battery operations. The vehicle battery measurement method/strategy may use a battery model to measure the battery pack in the vehicle to obtain several parameters during operation.

A vehicle battery measurement method may be implemented to eliminate the need for extensive offline testing. The vehicle battery measurement method may use the battery model (e.g., a black box model, an equivalent circuit model, an electrochemical model, etc.) to measure the battery pack in the vehicle to obtain an open circuit voltage during operation. The estimated battery parameters may include fluctuating trajectories which increase when the vehicle is in certain system modes including, charging mode, sustaining mode, or depleting (i.e., discharging) mode. These battery parameters tend to be sensitive to internal and external noises and environmental conditions when using the one or more battery models to estimate these parameters in real time.

In response to the measured open circuit voltage, the system may generate a battery open circuit voltage curve to provide information for predicting battery responses. For example, a battery terminal voltage at a given state of charge is a summation of an open circuit voltage and voltage changes caused by a battery current input profile. Other battery state variables, such as the state of charge and over potential, are computed using the measured open circuit voltage.

The open circuit voltage curve may be identified off-line through battery tests. The off-line testing may generate one or more predefined tables that makeup the open circuit voltage curve. On-board open circuit voltage curve identification may be possible using measured battery terminal voltages at different state of charge points for computing the open circuit voltages with the consideration of battery dynamics. The vehicle battery measurement method of on-board testing is done using one or more sensors, algorithms, and/or a combination thereof to measure the open circuit voltages at different battery state of charge points during vehicle operation. In the case of on-board identification, battery models may be used to estimate battery open circuit voltages.

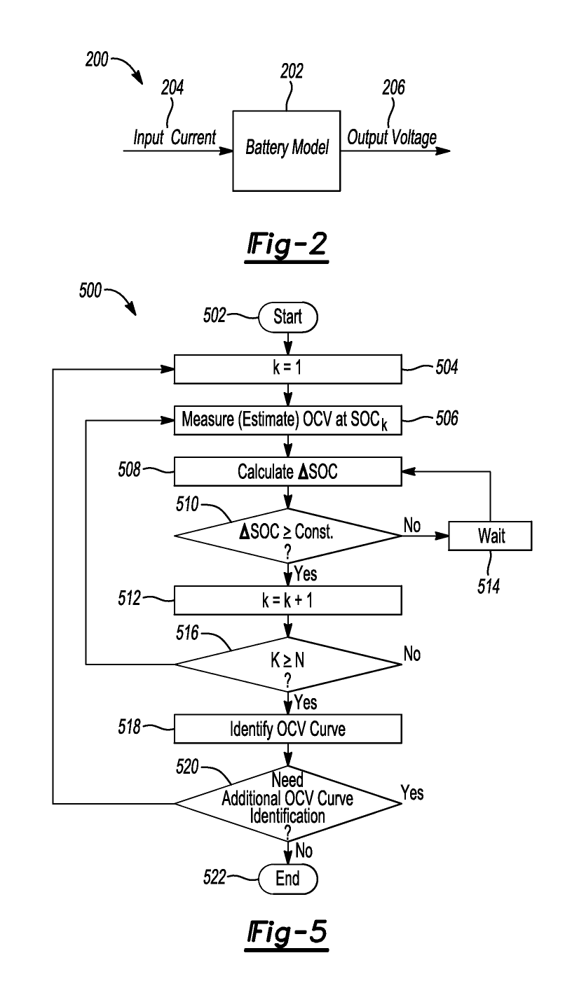

FIG. 2 is a schematic diagram 200 of a battery model 202 having current inputs 204 and voltage outputs 206 according to an embodiment. The battery model 202 may include one or more models including, but not limited to, an electrochemical model, an equivalent circuit model (e.g., a Randles Circuit Model), a black box model (e.g., an autoregressive model, a moving average model, an autoregressive moving average model, a neural network model), and/or a combination thereof.

Using input current profiles 204 and output voltage profiles 206 around a given state of charge, open circuit voltages may be estimated from state estimators based on the battery model 202. An estimation procedure to determine open circuit voltages may use various estimation approaches, such as an Extended Kalman filter and Unscented Kalman filter. Depending on the model structure, the battery model 202 may include additional inputs, such as temperature and battery state of charge (SOC). The additional inputs may be used to calculate battery parameters to control the battery pack.

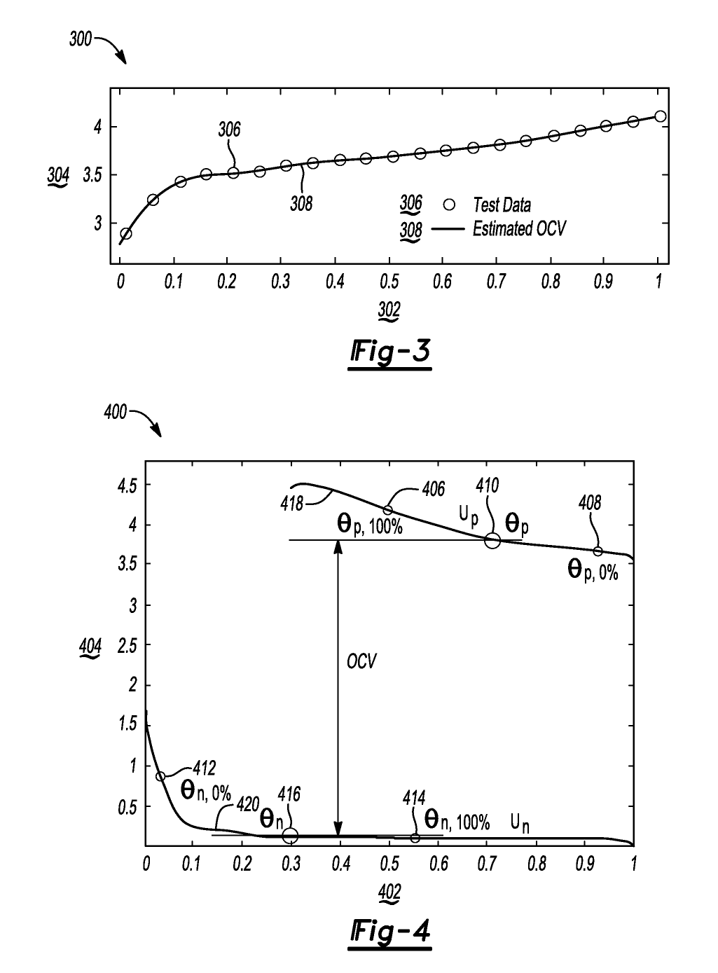

FIG. 3 is a graph 300 illustrating an example of an identified open circuit voltage curve 308 using multiple open circuit voltage points 306 with respect to a SOC and interpolating the open circuit voltage points. The graph has an x-axis 302 representing SOC of the battery and a y-axis 304 representing open circuit voltage (herein known as OCV). An interpolation method may include, but is not limited to, linear, polynomial, and/or spline.

The system may measure OCV data points 306 at different SOCs, when the battery is fully relaxed, i.e., in a steady state or in a resting period. The system may estimate OCV data points 306 with the consideration of battery dynamics such that the battery is not in a steady state. For example, the system may measure an OCV data point 306 having a value of three and five tenths voltage (3.5V) based on a twenty percent (20%) SOC. In another example, the system may measure an OCV data point 306 having a value of four and two tenths voltage (4.2V) based on a ninety nine percent (99%) SOC.

The system may receive a sufficient number of OCV data points 306 used to construct an estimated open circuit voltage profile curve 308 by interpolation. The sufficient number of OCV data points 306 may include at least ten or more data points. It may be possible to measure a sufficient number of OCV data points 306 to identify an OCV profile curve 308, but the OCV point measurements may require additional computational efforts. In contrast, a small number of OCV data points 306 may deteriorate the OCV profile curve identification accuracy.

The system may reduce the number of OCV data points 306 to identify an OCV profile curve 308 without deteriorating the OCV identification accuracy using pre-identified OCV curves. The pre-identified OCV curves include an OCV profile curve of the positive electrode and the negative electrode. The OCV profile curve using a reduced number of data points may be generated based on the pre-identified OCV curves and identified parameters defined in terms of normalized Li-ion concentrations at each electrode.

FIG. 4 is a graph illustrating the OCV calculation at different SOCs of the battery pack from pre-identified OCV curves of a positive electrode and a negative electrode. If OCV curves of a positive electrode and a negative electrode are known and the ranges of lithiation of each electrode can be identified, a battery OCV curve can be identified as well.

The graph has an x-axis 402 representing normalized Li-ion concentration of the battery and a y-axis 404 representing OCV of each electrode. An OCV of a battery cell is computed as the difference between the OCVs of a positive electrode and a negative electrode at a given SOC. The ranges of lithiation are defined corresponding to the battery state of charge at the positive electrode at one hundred percent (100%) 406 and zero percent (0%) 408, and for the negative electrode at zero percent (0%) 412 and one hundred percent (100%) 414.

An OCV curve with respect to the lithiation of the positive electrode material is depicted in 418, and an OCV curve with respect to the lithiation of the negative electrode material is depicted in 420.

The OCV at a given state of charge is computed from the following equation:

OCV=Uₚ(θₚ)−Uₙ(θₙ) (1)

wherein Uₚ(θₚ) is the OCV of the positive electrode, and Uₙ(θₙ) is the OCV of the negative electrode. The positive electrode Uₚ(θₚ) is expressed as Uₚ=f₁(θₚ), a function representing the OCV curve with respect to a normalized Li-ion concentration of the positive electrode θₚ. The negative electrode Uₙ(θₙ) is expressed as Uₙ=f₂(θₙ), a function representing the OCV curve with respect to a normalized Li-ion concentration of the negative electrode θₙ.

The normalized Li-ion concentrations of the positive electrode and the negative electrode are defined using the following equations:

$$\begin{matrix}{θ}_{p} = \frac{{c}_{p}}{{c}_{p , max}} {\vert}_{SS} at the positive electrode & ( 2 a ) \\ {θ}_{n} = \frac{{c}_{n}}{{c}_{n , max}} {\vert}_{SS} at the negative electrode & ( 2 b )\end{matrix}$$

wherein cₚ is the Li-ion concentration of the positive electrode in the battery cell, c_{p,max} is the maximum Li-ion concentration of the positive electrode, and the subscript SS represents a stead state of a battery dynamics.

The OCV of the positive electrode at a one hundred percent (100%) SOC point 406 has a greater value than the data point at a zero percent (0%) SOC point 408. The OCV of the negative electrode at a one hundred percent (100%) SOC point 414 is smaller than or equal to the value of the data point at a zero percent (0%) SOC point 412.

The corresponding state of charge at each electrode is expressed using the following equation:

$${SOC}_{p , SS} = \frac{{θ}_{p} - {θ}_{p , 0 \%}}{{θ}_{p , 100 \%} - {θ}_{p , 0 \%}} = {SOC}_{n , SS} = \frac{{θ}_{n} - {θ}_{n , 0 \%}}{{θ}_{n , 100 \%} - {θ}_{n , 0 \%}} \qquad ( 3 )$$

wherein the system may use an interpolated OCV curve of each electrode to determine the OCV data points of the positive electrode 410 and of the negative electrode 416.

From equation (3), the normalized Li-ion concentration at each electrode is calculated using the following equation:

θₚ=θ_{p,0%}+SOC_{p,SS}(θ_{p,100%}−θ_{p,0%}) (4a)

θₙ=θ_{n,0}%+SOC_{n,SS}(θ_{n,100%}−θ_{n,0%}) (4b)

wherein θ_{p,0}% is the normalized Li-ion concentration of the positive electrode at zero percent (0%) SOC, θ_{p,100%} is the normalized Li-ion concentration of the positive electrode at one hundred percent (100%) SOC, θ_{n,0%} is the normalized Li-ion concentration of the negative electrode at zero percent (0%) SOC, and θ_{n,100%} is the normalized Li-ion concentration of the negative electrode at one hundred percent (100%) SOC.

Using equations (1)-(4), the OCV curve is defined in the entire SOC range, i.e., from zero percent (0%) to one hundred percent (100%), in terms of the normalized Li-ion concentration at the positive electrode at θ_{p,0%}, θ_{p,100%}, and the normalized Li-ion concentration at the negative electrode at θ_{n,0%}, θ_{n,100%}.

The parameters may be identified by solving an optimization problem with multiple constraints minimizing the error between estimated OCV points and measured OCV points as formulated using the following equation:

$${min}_{{{θ}_{p , 0 \%} , {θ}_{p , 100 \%}}_{{θ}_{n , 0 \%} , {θ}_{n , 100 \%}}} \frac{{\sum }_{i = 1}^{N} {( {V}_{OC} ( {SOC}_{i} ) - {\hat{V}}_{OC} ( {θ}_{p , i} , {θ}_{n , i} ) )}^{2}}{N} \qquad ( 5 )$$

The optimization problem with multiple constraints in equation (5) is subject to the following equations:

θ_{p,i}=θ_{p,0%}+SOC_{p,i}(θ_{p,100%}−θ_{p,0%}) (6a)

θ_{n,i}=θ_{n,0%}+SOC_{n,i}(θ_{n,100%}−θ_{n,0%}) (6b)

\hat{V}_{OC}(θ_{p,i},θ_{n,i})=Uₚ(θ_{p,i})−Uₙ(θ_{n,i}) (6c)

\hat{V}_{OC}(θ_{p,100%},θ_{n,100%})=Vₘₐₓ (6d)

\hat{V}_{OC}(θ_{p,0%},θ_{n,0%})=Vₘᵢₙ (6e)

SOCᵢ=SOC_{p,i}=SOC_{n,i} (6f)

wherein \hat{V}_{OC}(θ_{p,i}, θ_{n,i}) is the estimated OCV at the i^{th} measurement, Vₘₐₓ is the battery output voltage upper limit, Vₘᵢₙ is the battery output voltage lower limit, SOCᵢ is the battery state-of-charge at the i^{th} OCV measurement, and N is the number of OCV measurements.

The model parameters to construct an OCV curve are the positive electrode at θ_{p,0%}, θ_{p,100}, and the negative electrode at θ_{n,0%}, θ_{n,100%} obtained by solving equation (5) subject to the constraints in equations (6a)-(6f).

The constraints in equations (6d) and (6e) may not be used for some cases, but the constraints in equations (6a)-(6c) and (6f) may always be satisfied.

The number of OCV measurements may be at least two, but the practical number of OCV measurements may be determined to achieve the desired OCV estimation accuracy regarding the Li-ion battery chemistry.

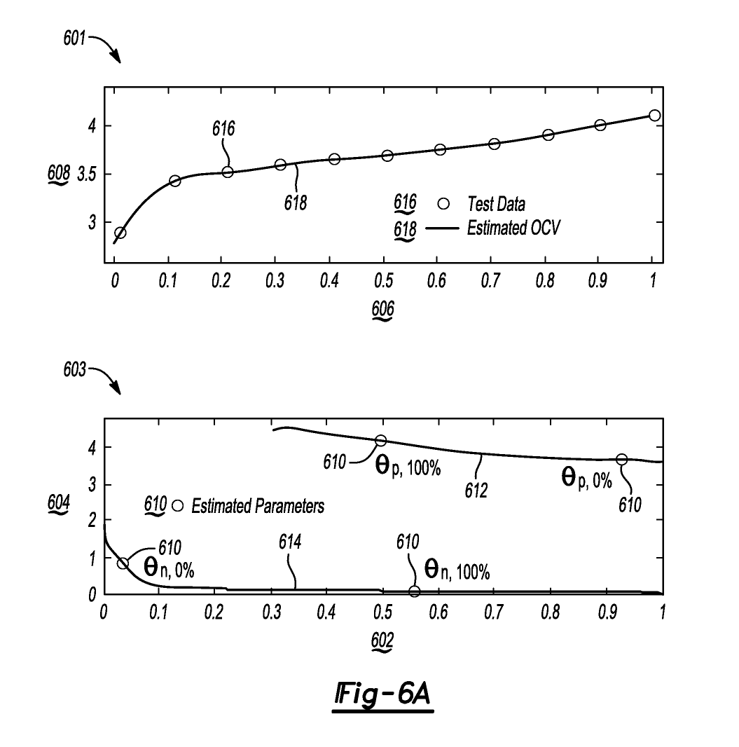

FIG. 5 is a flow chart of an algorithm for estimating OCV used to determine battery power limits in a battery management system according to an embodiment. The method 500 is implemented using software code contained within the vehicle control module. In other embodiments, the method 500 is implemented in other vehicle controllers, or distributed amongst multiple vehicle controllers.

Referring again to FIG. 5, the vehicle and its components illustrated in FIG. 1 are referenced throughout the discussion of the method 500 to facilitate understanding of various aspects of the present disclosure. The method 500 of controlling the battery parameter prediction in the hybrid electric vehicle may be implemented through a computer algorithm, machine executable code, or software instructions programmed into a suitable programmable logic device(s) of the vehicle, such as the vehicle control module, the hybrid control module, another controller in communication with the vehicle computing system, or a combination thereof. Although the various steps shown in the flowchart diagram appear to occur in a chronological sequence, at least some of the steps may occur in a different order, and some steps may be performed concurrently or not at all.

At step 502, during a key-on event which allows the vehicle to be powered on, the vehicle computing system may begin powering up the one or more modules. The powering up of the one or more modules may cause variables related to the battery management system to initialize before enabling one or more algorithms used to control the battery at step 504.

The initialized parameters in the one or more modules may be predetermined values or stored values at the last key-off event. Before enabling the algorithms at a key-on event, the parameters should be initialized. For example, the battery management method may initialize several variables including, but not limited to, the OCV data points, voltage limits, current limits, SOC range, and/or other battery related parameters.

At 506, the system may measure and/or estimate the OCV at a SOC data point using several types of sensors and/or algorithms. Once the system has received an OCV at a SOC data point, the system may calculate the SOC change from the time step of previous OCV measurement to the current time at step 508.

At step 510, if the SOC change is smaller than a predetermined constant, the battery controller waits for a predetermined amount of time to calculate a SOC change. If the SOC change is larger than and equal to a predetermined constant, the index k is increased by one at step 512. At step 514, if the battery is in a charge or discharge state, the system may wait until the battery is in a steady-state before measuring a new SOC data point.

For example, the SOC at the index k is fifty percent (50%) and the SOC at the index k+1 is fifty-one percent (51%), the SOC change may be small; therefore a large number of OCV measurements may be required to cover the entire SOC range and to identify an OCV curve. In contrast, if the SOC at the index k is sixty percent (60%) and the SOC at the index k+1 is forty percent (40%), the SOC change may be large enough to cover the entire SOC range with a small number of OCV measurements.

At step 516, the system may determine whether it has enough OCV data points to identify an OCV curve. If enough data points are received, the system may identify an OCV curve using the measurement data at different SOC points based on the embodiment at step 518.

At step 520, the system may determine that additional identification is needed to generate the OCV curve. The battery performance may change over the life of the battery based on a number of factors including, but not limited to, degree of lithiation of the electrodes, electrode capacity ratios, and/or electrode compositions. Battery control algorithms may use the identified OCV curve to account for the life of the battery.

At step 522, if the system detects a key-off event, the system may end the one or more algorithms used to manage the battery pack and/or the one or more battery cells. The vehicle computing system may have a vehicle key-off mode to allow the system to store one or more parameters in nonvolatile memory such that these parameters may be used by the system for the next key-on event. The one or more parameters may include OCV data points, SOC data points, and/or an OCV curve profile.

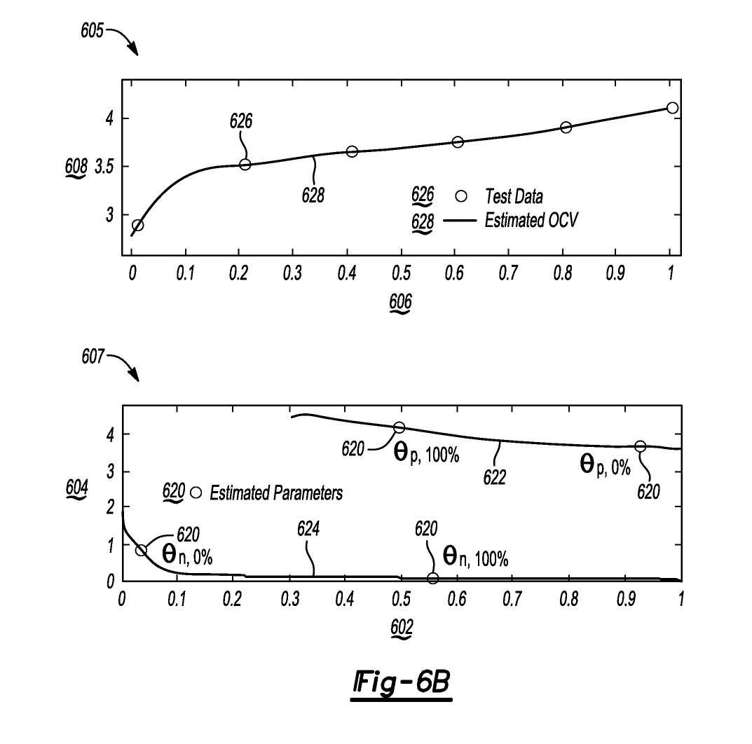

FIGS. 6A and 6B depicts identified OCV curves in graphs 601, 605 generated by positive 612, 622 and negative electrode 614, 624 OCV curves in graphs 603, 607. The OCV curves 618, 628 are estimated based on the positive and negative electrode OCV curves 612, 614, 622, 624 with identified lithiation limits of each electrode 610, 620. The OCV curve in graphs 601, 605 have a x-axis 606 representing SOC of the battery and a y-axis 608 representing OCV. The positive and negative electrode OCV curves in graphs 603, 607 have a x-axis 602 representing normalized Li-ion concentration of the battery and a y-axis 604 representing OCV of each electrode. The estimated parameters 610, 620 include normalized Li-ion concentrations of the positive and negative electrodes at one hundred percent (100%) SOC points and zero percent (0%) SOC points.

FIGS. 6A and 6B show the comparison of the identified OCV profile curves 618, 628 from a different number of test data points 616, 626 according to the embodiment. If an OCV curve is identifiable, the identified curves may be identical or close to each other regardless of the number of test data points 616, 626 as shown in FIGS. 6A and 6B. The battery management system may verify whether the estimated OCV parameters require additional measurement points (i.e., test data) 616, 626 before outputting an OCV curve 618, 628. The number of data points may be reduced to two in theory, but the practical number may be larger to get an improved OCV identification result.

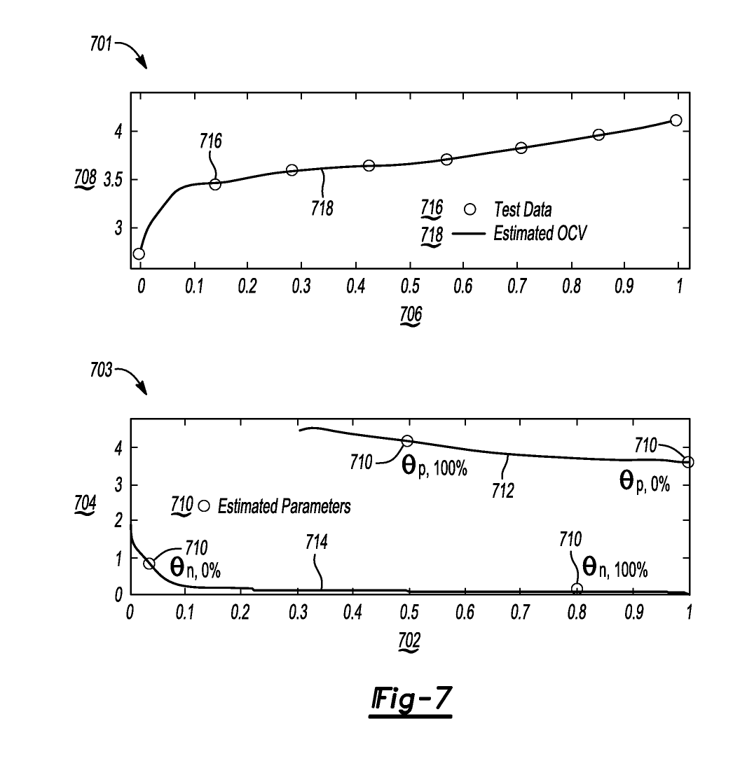

FIG. 7 are graphs of an OCV curve 718 constructed from the identified lithiation limits 710 of each electrode of a battery cell using measurement test data 716 at a different stage of battery life. The graph 701 has a x-axis 706 representing SOC of the battery and a y-axis 708 representing OCV. The graph 703 has a x-axis 702 representing normalized Li-ion concentration of the battery and a y-axis 704 representing OCV of each electrode. The OCV curve may change over the battery life, since the battery pack may age based on time, environmental conditions, battery use, and/or a combination thereof.

Compared to FIGS. 6A and 6B, the normalized Li-ion concentrations of the positive and negative electrode at one hundred percent (100%) SOC points are significantly different from those in FIG. 7. The different concentrations at each electrode result in a different OCV curve 718 in FIG. 7 compared to the OCV profile curves 618, 628 as shown in FIGS. 6A and 6B. If a battery OCV curve is changed at a given time period, the identified Li-ion concentrations of each electrode may be different.

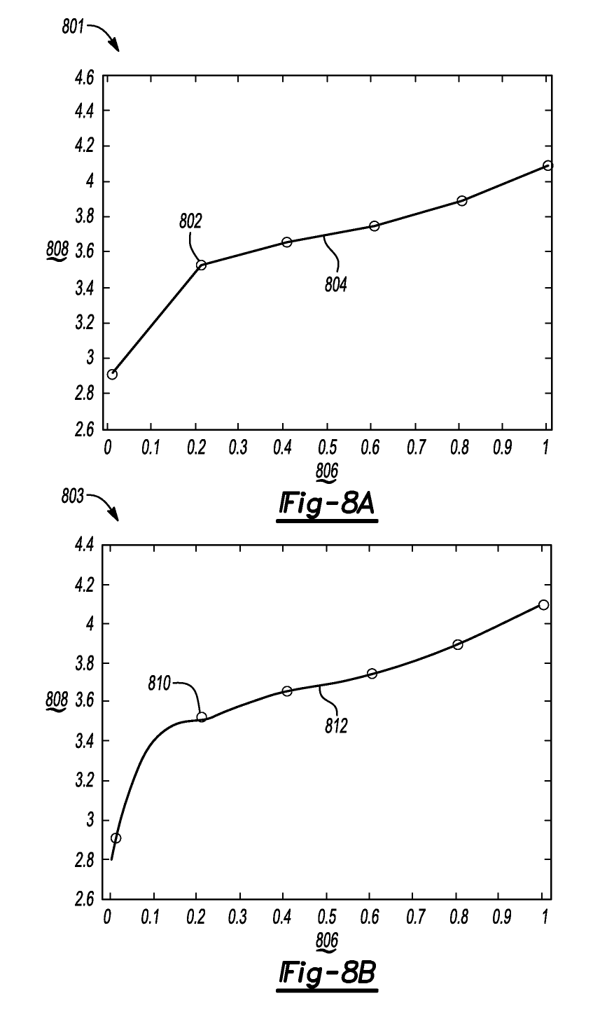

FIG. 8A is a graph 801 illustrating an identified OCV curve 804 using a small number of OCV measurements 802 based on a linear interpolation. The graph 801 has a x-axis 806 representing SOC of the battery and a y-axis 808 representing OCV test data points. The battery management system may generate a graph 801 of an estimated OCV curve 804 based on a predefined number of data points 802 requested by the system. For example, the system may request five, ten, fifteen, twenty, or fifty data points before generating the OCV curve 804. When the number of data is small, the linear interpolation cannot construct the OCV curve with sufficient accuracy.

FIG. 8B is a graph 803 illustrating an identified OCV curve 812 based on the measured electrodes, which identifies model parameters representing the normalized Li-ion concentrations at a one hundred percent (100%) SOC point and a zero percent (0%) SOC point of each electrode. The system may construct an OCV curve 812 from the identified model parameters and OCV curves of the positive and negative electrodes with a reduced number of OCV test data points 810. The graph 803 has a x-axis 806 representing SOC of the battery and a y-axis 808 representing OCV.

The OCV profile curve 812 in FIG. 8B illustrates improved OCV curve estimation as compared to the OCV curve 801 as shown in FIG. 8A. Therefore, OCV curves may be constructed using a limited number of measurement data as shown in FIG. 8B using the system and method disclosed. The system may continuously update battery parameters depending on the battery life as required.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and can be desirable for particular applications.

What is claimed is:

1. A battery management system comprising:
a battery pack; and
at least one controller programmed to
input current to the battery pack at each of at least two different states of charge, and
output open circuit voltage data for a state of charge other than the at least two different states of charge based on model parameters of positive and negative electrodes derived from open circuit voltage measurements corresponding to the input.

2. The system of claim 1, wherein the at least two different states of charge include zero and one hundred percent state of charge.

3. The system of claim 1, wherein the at least one controller is further programmed to obtain the measurements during vehicle operation.

4. The system of claim 1, wherein the at least one controller is further programmed to estimate the open circuit voltage data using an Extended Kalman filter.

5. The system of claim 1, wherein the at least one controller is further programmed to derive the model parameters from an optimization problem with multiple constraints.

6. The system of claim 5, wherein the optimization problem has a cost function that minimizes errors between estimated open circuit voltage data and measured open circuit voltage data.

7. The system of claim 1, wherein the at least one controller is further programmed to output terminal voltage based on the open circuit voltage data.

8. The system of claim 7, wherein the at least one controller is further programmed to control the battery pack based on the terminal voltage.

9. A vehicle comprising:
a battery pack; and
at least one controller programed to output open circuit voltage data for a given state of charge of the battery pack based on (i) model parameters of battery pack positive and negative electrodes represented by normalized Li-ion concentrations at zero and one hundred percent states of charge and (ii) model parameters of at least two open circuit voltages each associated with a different state of charge.

10. The vehicle of claim 9, wherein the at least one controller is further programmed to predict battery pack terminal voltage based on the open circuit voltage data.

11. The vehicle of claim 10, wherein the at least one controller is further programmed to output state of charge, power fade, capacity fade, or instantaneous available power based on the battery pack terminal voltage.

12. The vehicle of claim 9, wherein the at least two open circuit voltages are defined by measured or estimated data.

13. The vehicle of claim 12, wherein the measured or estimated data is obtained during vehicle operation.

14. The vehicle of claim 9, wherein the model parameters are derived from an optimization problem having a cost function to minimize errors between estimated open circuit voltage data and measured open circuit voltage data subject to multiple constraints.

15. A method for managing a battery comprising:
outputting open circuit voltage data for a given state of charge of the battery based on (i) model parameters of battery positive and negative electrodes represented by normalized Li-ion concentrations at zero and one hundred percent states of charge and (ii) model parameters of at least two open circuit voltages each associated with a different state of charge;
outputting battery terminal voltage based on the open circuit voltage data; and
controlling operation of the battery based on the battery terminal voltage.

16. The method of claim 15 further comprising outputting state of charge, power fade, capacity fade, or instantaneous available power based on the battery terminal voltage and further controlling operation of the battery based on the state of charge, power fade, capacity fade, or instantaneous available power.

17. The method of claim 15, wherein the at least two open circuit voltages are defined by measured or estimated data.

18. The method of claim 17, wherein the measured or estimated data is obtained during vehicle operation.

19. The method of claim 15, wherein the model parameters are derived from an optimization problem that minimizes errors between estimated open circuit voltage data and measured open circuit voltage data subject to multiple constraints.
